(19) United States
(12) Patent Application Publication
(10) Pub. No.: US 2026/0018395 A1
(43) Pub. Date: Jan. 15, 2026

(54) Atmospheric Plasma Activation for Hybrid Bonding

(71) Applicant: Applied Materials, Inc., Santa Clara, CA (US)

(72) Inventors: Karthik Narayanan BALAKRISHNAN, Singapore (SG); Ananthkrishna JUPUDI, Singapore (SG); Gaurav MEHTA, Singapore (SG); Raymond HUNG, Palo Alto, CA (US)

(21) Appl. No.: 18/770,602

(22) Filed: Jul. 11, 2024

(51) Int. Cl. H01J 37/32; H01L 23/00

(52) U.S. Cl. CPC H01J 37/32825; H01J 37/32715; H01J 37/32743; H01L 24/74; H01L 24/80; H01J 2237/20228; H01J 2237/20278; H01J 2237/204; H01J 2237/336; H01L 2224/74; H01L 2224/80009; H01L 2224/80092; H01L 2224/80895; H01L 2224/80896; H01L 2924/40

(57) ABSTRACT

Embodiments of multi-chamber processing tools are provided herein. In some embodiments, a multi-chamber processing tool includes: an equipment front end module (EFEM) having one or more loadports for receiving one or more types of substrates; a plurality of atmospheric modular mainframes coupled to each other and having a first atmospheric modular mainframe coupled to the EFEM, wherein each of the plurality of atmospheric modular mainframes include a transfer chamber and one or more process chambers coupled to the transfer chamber, wherein at least one of the plurality of atmospheric modular mainframes includes a bonder chamber, wherein the transfer chamber includes a buffer having a plurality of shelves for supporting the one or more types of substrates and includes a transfer robot; and an atmospheric plasma activation module disposed in the transfer chamber or one of the one or more process chambers.

### FIELD

Embodiments of the present disclosure generally relate to substrate processing equipment.

### BACKGROUND

Substrates undergo various processes during the fabrication of semiconductor integrated circuit devices. Some of these processes include wafer dicing, in which a processed wafer is placed on a dicing tape and is cut or separated into a plurality of die or chiplets. Once the wafer has been diced, the chiplets typically stay on the dicing tape until they are extracted and bonded to a substrate. Conventional processing tools for cleaning, dicing, and bonding chiplets to a substrate generally include multiple tools or a single linear robot housed in a mainframe tool. A number of chambers or process modules may be coupled to the mainframe and generally determine a length of the mainframe and the single linear robot. However, the tool comprising a single linear robot housed in the mainframe provides limited expandability and processing throughput. Moreover, exposure of the surface of a substrate to a plasma (i.e., plasma activation) is one of the steps for a hybrid bonding process. However, typically, plasma activation is performed in a vacuum chamber, which requires a tool footprint dedicated for such a chamber and which is also an expensive solution.

Accordingly, the inventors have provided herein improved multi-chamber processing tools and methods of processing substrates using such multi-chamber processing tools.

### SUMMARY

Embodiments of multi-chamber processing tools are provided herein. In some embodiments, a multi-chamber processing tool includes: an equipment front end module (EFEM) having one or more loadports for receiving one or more types of substrates; a plurality of atmospheric modular mainframes coupled to each other and having a first atmospheric modular mainframe coupled to the EFEM, wherein each of the plurality of atmospheric modular mainframes include a transfer chamber and one or more process chambers coupled to the transfer chamber, wherein at least one of the plurality of atmospheric modular mainframes includes a bonder chamber, wherein the transfer chamber includes a buffer having a plurality of shelves for supporting the one or more types of substrates and includes a transfer robot; and an atmospheric plasma activation module disposed in the transfer chamber or one of the one or more process chambers.

In some embodiments, a multi-chamber processing tool includes: an equipment front end module (EFEM) having one or more loadports for receiving one or more types of substrates; and a plurality of atmospheric modular mainframes coupled to each other and having a first atmospheric modular mainframe coupled to the EFEM, wherein each of the plurality of atmospheric modular mainframes include a transfer chamber and one or more process chambers coupled to the transfer chamber, wherein at least one of the plurality of atmospheric modular mainframes include a bonder chamber and at least one of the plurality of atmospheric modular mainframes include a plasma activation stage for supporting a substrate of the one or more types of substrates, wherein the transfer chamber includes a buffer configured to hold a plurality of the one or more types of substrates and includes a transfer robot configured to transfer the one or more types of substrates between the buffer, the one or more process chambers, and a buffer disposed in an adjacent atmospheric modular mainframe of the plurality of atmospheric modular mainframes; and an atmospheric plasma activation module configured to form an atmospheric pressure plasma and to expose a surface of the substrate to the atmospheric pressure plasma, wherein the plasma activation stage is configured to move with respect to the atmospheric plasma activation module.

In some embodiments, a method of bonding a plurality of chiplets onto a substrate, includes: loading a first type of substrate onto a first loadport of an equipment front end module (EFEM) of a multi-chamber processing tool having a plurality of atmospheric modular mainframes; using an EFEM robot to transfer the first type of substrate to a first buffer disposed in a first atmospheric modular mainframe of the plurality of atmospheric modular mainframes coupled to the EFEM; transferring the first type of substrate to the first atmospheric plasma activation module to activate the first type of substrate; using the EFEM robot to transfer a second type of substrate, having a plurality of chiplets, to the first buffer; transferring the second type of substrate to the a second atmospheric plasma activation module to activate the second type of substrate; transferring at least one of the plurality of activated chiplets from the second type of substrate to the activated first type of substrate in a bonder chamber of a first atmospheric modular mainframe of the plurality of atmospheric modular mainframes; and bonding the at least one of the plurality of activated chiplets to the activated first type of substrate in the bonder chamber.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic top view of a multi-chamber processing tool in accordance with at least some embodiments of the present disclosure.

FIG. 2 depicts a top view of a tape frame substrate in accordance with at least some embodiments of the present disclosure.

FIG. 3 depicts an isometric schematic top view of a transfer chamber in accordance with at least some embodiments of the present disclosure.

FIG. 4A depicts a schematic top view of an interface between a plasma activation module and a substrate in accordance with at least some embodiments of the present disclosure.

FIG. 4B depicts a schematic top view of an interface between a plasma activation module and a substrate in accordance with at least some embodiments of the present disclosure.

FIG. 5 depicts an isometric view of a plasma activation chamber in accordance with at least some embodiments of the present disclosure.

FIG. 6 depicts a flow chart of a method of bonding a plurality of chiplets onto a substrate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of multi-chamber processing tools having an atmospheric plasma activation module are provided herein. The atmospheric plasma activation module advantageously activates substrates in an atmospheric pressure plasma environment so that no separate vacuum chamber is required to perform a substrate activation process. With no separate vacuum chamber or pump down necessary, the multi-chamber processing tool advantageously is configured to process substrates in a cheaper, less complex, and faster manner, increasing processing throughput.

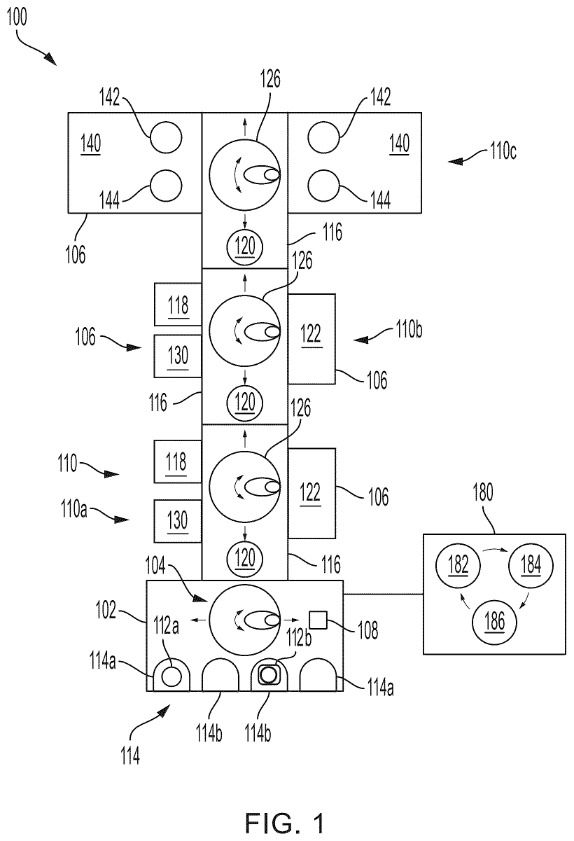

FIG. 1 depicts a schematic top view of a multi-chamber processing tool 100 in accordance with at least some embodiments of the present disclosure. The multi-chamber processing tool 100 is generally for hybrid bonding of chiplets to a substrate, however, the multi-chamber processing tool may be any suitable multi-chamber tool that requires plasma activation of a substrate. The multi-chamber process tool 100 generally includes an equipment front end module (EFEM) 102 and a plurality of atmospheric modular mainframes (AMMs) 110 that are serially coupled to the EFEM 102. The plurality of AMMs 110 are configured to shuttle one or more types of substrates 112 from the EFEM 102 through the multi-chamber process tool 100 and perform one or more processing steps to the one or more types of substrates 112. Each of the plurality of AMMs 110 generally include a transfer chamber 116 and one or more process chambers 106 coupled to the transfer chamber 116 to perform the one or more processing steps. The plurality of AMMs 110 are coupled to each other via their respective transfer chamber 116 to advantageously provide modular expandability and customization of the multi-chamber process tool 100. As depicted in FIG. 1, the plurality of AMMs 110 comprise three AMMs, where a first AMM 110a is coupled to the EFEM 102, a second AMM 110b is coupled to the first AMM 110a, and a third AMM 110c is coupled to the second AMM 110b.

The EFEM 102 includes a plurality of loadports 114 for receiving one or more types of substrates 112. In some embodiments, the one or more types of substrates 112 include 200 mm wafers, 300 mm wafers, 450 mm wafers, tape frame substrates, carrier substrates, silicon substrates, glass substrates, or the like. In some embodiments, the plurality of loadports 114 include at least one of one or more first loadports 114a for receiving a first type of substrate 112a or one or more second loadports 114b for receiving a second type of substrate 112b. In some embodiments, the first type of substrates 112a have a different size than the second type of substrates 112b. In some embodiments, the second type of substrates 112b include tape frame substrates or carrier substrates. In some embodiments, the second type of substrates 112b include a plurality of chiplets disposed on a tape frame or carrier plate. In some embodiments, the second type of substrates 112b may hold different types and sizes of chiplets. As such, the one or more second loadports 114b may have different sizes or receiving surfaces configured to load the second type of substrates 112b having different sizes.

In some embodiments, the plurality of loadports 114 are arranged along a common side of the EFEM 102. Although FIG. 1 depicts a pair of the first loadports 114a and a pair of the second loadports 114b, the EFEM 102 may include other combinations of loadports such as one first loadport 114a and three second loadports 114b.

In some embodiments, the EFEM 102 includes a scanning station 108 having substrate ID readers for scanning the one or more types of substrates 112 for identifying information. In some embodiments, the substrate ID readers include a bar code reader or an optical character recognition (OCR) reader. The multi-chamber processing tool 100 is configured to use any identifying information from the one or more types of substrates 112 that are scanned to determine process steps based on the identifying information, for example, different process steps for the first type of substrates 112a and the second type of substrates 112b. In some embodiments, the scanning station 108 may also be configured for rotational movement to align the first type of substrates 112a or the second type of substrates 112b. In some embodiments, the one or more of the plurality of AMMs 110 include a scanning station 108.

An EFEM robot 104 is disposed in the EFEM 102 and configured to transport the first type of substrates 112a and the second type of substrates 112b between the plurality of loadports 114 to the scanning station 108. The EFEM robot 104 may include substrate end effectors for handling the first type of substrates 112a and second end effectors for handling the second type of substrates 112b. The EFEM robot 104 may rotate or rotate and move linearly.

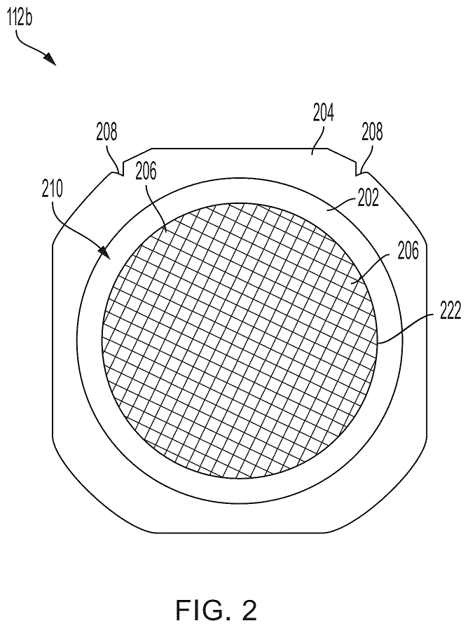

FIG. 2 depicts a tape frame substrate, for example, a second type of substrate 112b, in accordance with at least some embodiments of the present disclosure. In some embodiments, the second type of substrate 112b is a tape frame substrate that generally comprises a layer of backing tape 202 surrounded by a tape frame 604. In use, a plurality of chiplets 206 can be attached to a backing tape 222. The plurality of chiplets 206 are generally formed via a singulation process that dices a semiconductor wafer 210 into the plurality of chiplets 206 or dies. In some embodiments, the tape frame 204 is made of metal, such as stainless steel. The tape frame 204 may have one or more notches 208 to facilitate alignment and handling. For a semiconductor wafer 210 having a 300 mm diameter, the tape frame 204 may have a width of about 340 mm to about 420 mm and a length of about 340 mm to about 420 mm. The second type of substrate 112b may alternatively be a carrier plate configured to have the plurality of chiplets 206 coupled to the carrier plate.

Referring back to FIG. 1, the one or more process chambers 106 may be sealingly engaged with the transfer chamber 116. The transfer chamber 116 generally operates at atmospheric pressure but may be configured to operate at vacuum pressure. For example, the transfer chamber 116 may be a non-vacuum chamber configured to operate at an atmospheric pressure of about 700 Torr or greater. Additionally, while the one or more process chambers 106 are generally depicted as orthogonal to the transfer chamber 116, the one or more process chambers 106 may be disposed at an angle with respect to the transfer chamber 116 or a combination of orthogonal and at an angle.

The transfer chamber 116 includes a buffer 120 configured to hold one or more first type of substrates 112a. In some embodiments, the buffer 120 is configured to hold one or more of the first type of substrates 112a and one or more of the second type of substrates 112b. The transfer chamber 116 includes a transfer robot 126 configured to transfer the first type of substrates 112a and the second type of substrates 112b between the buffer 120, the one or more process chambers 106, and a buffer disposed in an adjacent AMM of the plurality of AMMs 110. For example, the transfer robot 126 in the first AMM 110a is configured to transfer the first type of substrates 112a and the second type of substrates 112b between the first AMM 110a and the buffer 120 in the second AMM 110b. In some embodiments, the buffer 120 is disposed within the interior volume of the transfer chamber 116, advantageously reducing the footprint of the overall tool. In addition, the buffer 120 can be open to the interior volume of the transfer chamber 116 for ease of access by the transfer robot 126. In some embodiments, the buffer 120 may also be configured to perform a radiation process on the second type of substrate 112b.

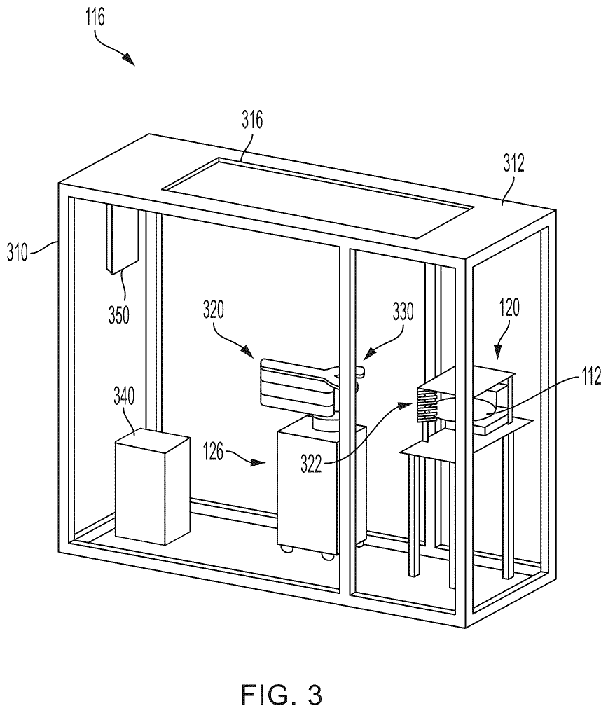

FIG. 3 depicts an isometric schematic top view of a transfer chamber in accordance with at least some embodiments of the present disclosure. The transfer chamber 116 is depicted in simplified form to describe the key components. The transfer chamber 116 generally includes a frame 310 that is covered with plates (top plate 312 shown in FIG. 3, side plates not shown) to enclose the transfer chamber 116. In some embodiments, the transfer chamber 116 has a width less than a length. The top plate 312 (or side plates) may include an access opening 316 that is selectively opened or closed for servicing the transfer chamber 116. The side plates include openings at interfaces with at least one of the one or more process chambers 106, the EFEM 102, or adjacent transfer chambers. While FIG. 3 shows the transfer chamber 116 having a rectangular or box shape, the transfer chamber 116 may have any other suitable shape, such as cylindrical, hexagonal, or the like. The one or more process chamber 106 may be coupled orthogonally to the transfer chamber 116 or may be coupled at an angle with respect to the transfer chamber 116.

In some embodiments, the transfer chamber is a non-vacuum chamber. The transfer chamber 116 may have one or more environmental controls. For example, an airflow opening (e.g., access opening 316) in the transfer chamber 116 may include a filter to filter the airflow entering the transfer chamber 116. Other environmental controls may include one or more of humidity control, static control, temperature control, or pressure control.

The buffer 120 is housed within the frame 310, for example, in an interior volume of the frame 310. In some embodiments, the buffer 120 is configured to rotate to align the first type of substrates 112a and the second type of substrates 112b in a desired manner. In some embodiments, the buffer is configured to hold the one or more types of substrates 112 in a vertical stack advantageously reducing the footprint of the transfer chamber 116. For example, in some embodiments, the buffer 120 includes a plurality of shelves 322 for storing or holding one or more first type of substrates 112a and one or more second type of substrates 112b. In some embodiments, the plurality of shelves 322 are disposed in a vertically spaced apart configuration.

The transfer chamber 116 may include an atmospheric plasma activation module 350, or plasma module 350, disposed therein in a suitable manner. The plasma module 350 is generally a small profile module advantageously configured to form an atmospheric pressure plasma and to expose a surface of the substrate 112 to the atmospheric pressure plasma. In some embodiments, the plasma module 350 is smaller in size than a width of the substrate 112. The small form of the plasma module 350 advantageously reduces the footprint of the multi-chamber processing tool. For example, the plasma module 350 may be coupled to the frame 310, top plate 312, or side plates, of the transfer chamber 116 and thus advantageously not require a separate plasma activation chamber. The plasma module 350 may comprise a frame or enclosure having a suitable beam plasma source disposed therein. The beam plasma source is configured to emit a plasma beam that can clean and activate substrates for improved adhesion. The beam plasma source, or plasma beam, may comprise one or more of active oxygen, nitrogen, or hydrogen atoms.

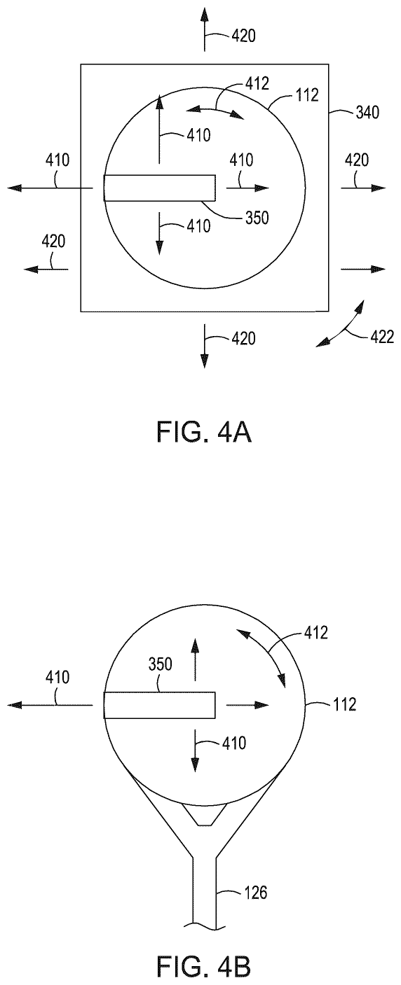

In some embodiments, the plasma module 350 may be coupled to a stage 340 disposed in the transfer chamber 116. In some embodiments, the plasma module 350 is fixedly coupled within the transfer chamber 116. In some embodiments, the plasma module 350 is configured to move in lateral directions (described in more detail in FIGS. 4A and 4B). In some embodiments, the plasma module 350 is configured to rotate within the transfer chamber 116. In some embodiments, the substrate 112 may be configured to rotate within the transfer chamber 116 below the plasma module 350. In some embodiments, the stage 340 may be configured as an aligner to align the substrate 112 for transfer, for example, via the transfer robot 126. As such, the stage 340 may advantageously serve a dual purpose of alignment and plasma activation.

The transfer robot 126 is generally housed within the frame 310. The transfer robot 126 is configured for rotational or rotational and linear movement within the transfer chamber 116. In some embodiments, the transfer robot 126 moves linearly via rails on a floor of the transfer chamber 116 or via wheels under the transfer robot 126. The transfer robot 126 includes a telescoping arm 720 having one or more end effectors 730 that can extend into the one or more process chamber 106 and into adjacent AMMs. In some embodiments, the one or more end effectors 330 comprise substrate end effectors for handling the first type of substrates 112a and second end effectors for handling the second type of substrates 112b. In some embodiments, for a transfer chamber 116 having a length of about 2.0 to about 2.5 meters, the telescoping arm 320 may have a stroke length of up to about 1.0 meter. In some embodiments, the EFEM robot 104 is the same type and configuration as the transfer robot 126 for enhanced commonality of parts.

FIG. 4A depicts a schematic top view of an interface between the plasma module 350 and a substrate of the one or more types of substrates 112 in accordance with at least some embodiments of the present disclosure. In some embodiments, the substrate is disposed on a stage 340, or plasma activation stage. In some embodiments, the plasma module 350 is disposed above the stage 340. The plasma module 350 may have a size smaller than the substrate and therefore, at least one of the plasma module 350 or the substrate may be indexed to fully scan, or activate, the substrate with plasma. Indexing generally includes moving at least one of the substrate or the plasma module 350 with respect to each other.

In some embodiments, indexing may include lateral movements 420 of the stage 340. In some embodiments, indexing may include lateral movements 410 of the plasma module 350. In some embodiments, indexing may include rotational movements 412 of the plasma module 350. In some embodiments, indexing may include rotation movements 422 of the stage 340. In some embodiments, indexing may include a combination of the above mentioned lateral and rotational movements. In some embodiments, the stage 340 may be moved vertically up or down to move the substrate closer or further away from the plasma module 350. In some embodiments, the plasma module 350 may be moved vertically up or down to move the substrate closer or further away from the plasma module 350.

FIG. 4B depicts a schematic top view of an interface between a plasma module 350 and a substrate 112 in accordance with at least some embodiments of the present disclosure. In some embodiments, the transfer robot 126 is configured to index the one or more types of substrates 112 with respect to the plasma module 350. In some embodiments, during plasma activation, the transfer robot 126 is fixed and the plasma module 350 may move via the lateral movements 410 or the rotational movements 412. In some embodiments, during plasma activation, the plasma module 350 is fixed and the transfer robot 126 is configured to move the substrate via lateral or rotational movements.

Referring back to FIG. 1, the one or more process chambers 106 may include atmospheric chambers that are configured to operate under atmospheric pressure and vacuum chambers that are configured to operate under vacuum pressure. Examples of the atmospheric chambers may generally include wet clean chambers, radiation chambers, heating chambers, metrology chambers, bonder chambers, or the like. Examples of vacuum chambers may include plasma chambers. The types of atmospheric chambers discussed above may also be configured to operate under vacuum, if needed. The one or more process chambers 106 may be any process chambers or modules needed to perform a bonding process, a dicing process, a cleaning process, a plating process, or the like.

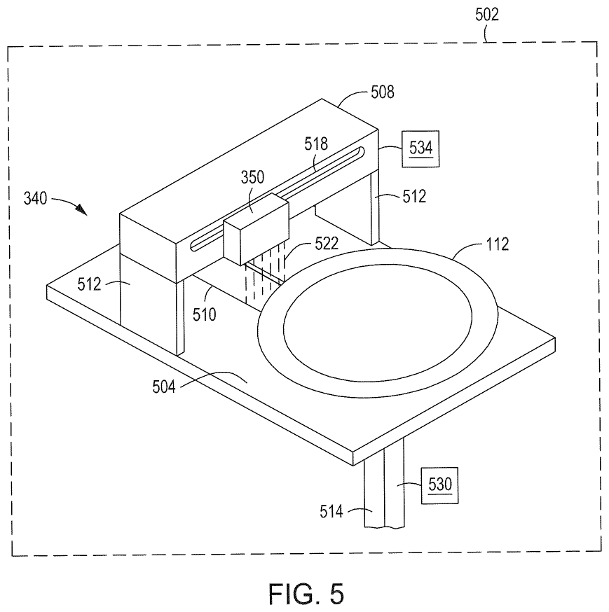

In some embodiments, the one or more process chambers 106 of each of the plurality of AMMs 110 include at least one of a wet clean chamber 122, a degas chamber 130, or a bonder chamber 140 such that the multi-chamber processing tool 100 includes at least one wet clean chamber 122, at least one degas chamber 130, and at least one bonder chamber 140. In some embodiments, the one or more process chambers 106 include a plasma activation chamber 118 configured to activate the substrates 112 (discussed in more detail with respect to FIG. 5). While the plasma activation chamber 118 adds an additional chamber as compared to the plasma module disposed in the transfer chamber 116, the small footprint of the plasma module 350 and functionally of forming a plasma at atmospheric pressure provide advantages of a smaller footprint than vacuum based activation chambers, reduced processing time, and lower cost to manufacture.

The wet clean chamber 122 is configured to perform a wet clean process to clean the one or more types of substrates 112 via a fluid, such as water. The wet clean chamber 122 may include a first wet clean chamber for cleaning the first type of substrates 112a and a second wet clean chamber for cleaning the second type of substrates 112b. The degas chamber 130 is configured to perform a degas process to remove moisture from the substrates 112. In some embodiments, the degas chamber 130 includes a first degas chamber for the first type of substrates and a second degas chamber for the second type of substrates.

The bonder chamber 140 (or bonding chamber) is configured to transfer and bond at least a portion of the plurality of chiplets 206 to one of the first type of substrates 112a. The bonder chamber 140 generally includes a first support 142 to support one of the first type of substrates 112a and a second support 144 to support one of the second type of substrates 112b.

In some embodiments, the one or more process chambers 106 of the first AMM 110a includes a wet clean chamber 122, a degas chamber 130, and a plasma activation chamber 118. In some embodiments, the one or more process chambers 106 of the second AMM 110b includes a wet clean chamber 122, a degas chamber 130, and a plasma activation chamber 118. In some embodiments, a last AMM of the plurality of AMMs 110, for example the third AMM 110c of FIG. 1, includes one or more bonder chambers 140 (two shown in FIG. 1). In some embodiments, a first of the two bonder chambers is configured to remove and bond chiplets having a first size and a second of the two bonder chambers is configured to remove and bond chiplets having a second size.

A controller 180 controls the operation of any of the multi-chamber processing tools described herein, including the multi-chamber processing tool 100. The controller 180 may use a direct control of the multi-chamber processing tool 100, or alternatively, by controlling the computers (or controllers) associated with the multi-chamber processing tool 100. In operation, the controller 180 enables data collection and feedback from the multi-chamber processing tool 100 to optimize performance of the multi-chamber processing tool 100. The controller 180 generally includes a Central Processing Unit (CPU) 182, a memory 184, and a support circuit 186. The CPU 182 may be any form of a general-purpose computer processor that can be used in an industrial setting. The support circuit 186 is conventionally coupled to the CPU 182 and may comprise a cache, clock circuits, input/output subsystems, power supplies, and the like. Software routines, such as a method as described below may be stored in the memory 184 and, when executed by the CPU 182, transform the CPU 182 into a specific purpose computer (controller 180). The software routines may also be stored and/or executed by a second controller (not shown) that is located remotely from the multi-chamber processing tool 100.

The memory 184 is in the form of computer-readable storage media that contains instructions, when executed by the CPU 182, to facilitate the operation of the semiconductor processes and equipment. The instructions in the memory 184 are in the form of a program product such as a program that implements the method of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

FIG. 5 depicts an isometric view of a plasma activation chamber 118 in accordance with at least some embodiments of the present disclosure. The plasma activation chamber 118 is generally configured to operate under atmospheric pressure. In some embodiments, the plasma activation chamber includes the stage 340, where similar to as discussed above with respect to FIG. 4A, at least one of the stage 340 or the plasma module 350 is configured to move laterally or rotationally within the plasma activation chamber 118. The plasma activation chamber 118 may include an enclosure 502 that at least partially encloses the stage 340.

In some embodiments, the stage 340 may include a base plate 504 and a plasma module support 508 disposed above the base plate 504. In some embodiments, the plasma module support 508 is coupled to the base plate 504 via one or more support arms 512. The plasma module support 508 is moveably coupled to the plasma module 350. The plasma module support 508 may include a slot 518 for facilitating lateral movement of the plasma module 350. In some embodiments, the base plate 504 includes a slot 510 for facilitating lateral movement of the substrate 112. The stage 340 may include a substrate support 514 for supporting the substrate 112. In some embodiments, the substrate support 514 is configured to elevate the substrate 112 above an upper surface of the base plate 504 to prevent grinding therebetween. The substrate support 514 may be coupled to an actuator 530 or other suitable mechanism for moving the substrate 112 (lateral or rotational movements) within the slot 510. The substrate support 514 may comprise a vacuum chuck to hold the substrate 112 via backside vacuum. A motion system 534 comprising an actuator or other suitable mechanism may be coupled to the plasma module support 508 for moving the plasma module 350 with respect to the slot 518.

In use, the plasma module 350 advantageously may form a plasma 522 at atmospheric pressure and direct the plasma 522 at the exposed portions of the substrate 112. The lateral and/or rotational movements of the substrate 112 with respect to the plasma module 350 (e.g., indexing) facilitates activation of an entire exposed surface of the substrate 112. For example, the substrate 112 may be moved along slot 510 for a first pass while the plasma module 350 is fixed at a first position The plasma module 350 then be moved to a second position and the substrate 112 may be moved along slot 510 for a second pass while the plasma module 350 is fixed at the second position. The foregoing process may continue until the entire substrate 112 is activated, or desired portions of the substrate 112 are activated, with the plasma 522. In some embodiments the plasma module 350 may be fixed to a first position and the substrate 112 may be rotated via the actuator 530 or suitable rotational mechanism to expose different portions of the substrate 112 to the plasma 522. In some embodiments, an activation gas such as nitrogen (N2) may be flowed across an upper surface of the substrate 112 to improve activation performance.

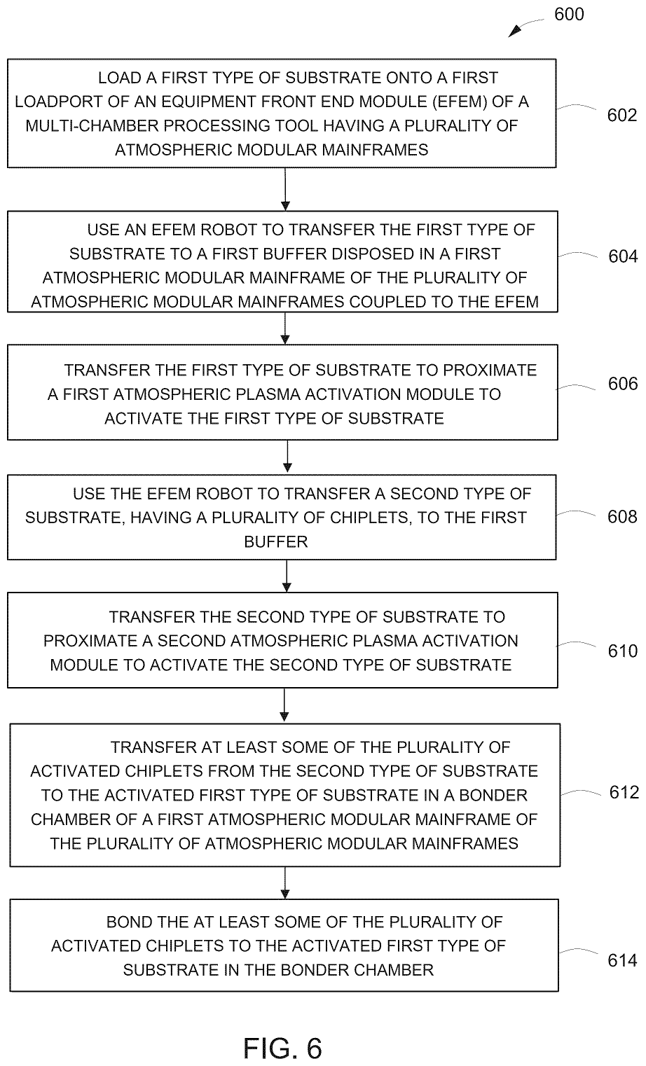

FIG. 6 depicts a flow chart of a method 600 of bonding a plurality of chiplets onto a substrate in accordance with at least some embodiments of the present disclosure. The method 600, at 602, includes loading a first type of substrate (e.g., first type of substrate 112a) onto a first loadport (e.g., first loadport 114a) of an equipment front end module (EFEM) (e.g., EFEM 102) of a multi-chamber processing tool having a plurality of atmospheric modular mainframes (e.g., plurality of AMMs (110).

The method 600, at 604, includes using an EFEM robot (e.g., EFEM robot 104) to transfer the first type of substrate to a first buffer (e.g., buffer 120) disposed in a first AMM of the plurality of AMMs coupled to the EFEM. In some embodiments, identifying information of the first type of substrate may be scanned via a scanning station (e.g., scanning station 108) prior to transfer to the first buffer.

The method 600, at 606, includes transferring the first type of substrate to a first atmospheric plasma activation module (e.g. plasma module 350) to activate the first type of substrate. In some embodiments, the first type of substrate is activated at atmospheric pressure. In some embodiments, the first type of substrate is activated in a first plasma activation chamber (e.g., plasma activation chamber 118) via the first plasma activation module. In some embodiments, the first type of substrate is activated in a transfer chamber (e.g., transfer chamber 116) of one of the plurality of AMMs.

In some embodiments, the first type of substrate is activated via indexing the first type of substrate with respect to the first plasma activation module. Indexing generally includes moving at least one of the first type of substrate or the first plasma activation module with respect to each other. In some embodiments, indexing may include lateral movements. In some embodiments, indexing may include rotational movements. In some embodiments, indexing may include a combination of lateral and rotational movements.

The method 600, at 608, includes using the EFEM robot to transfer a second type of substrate (e.g., second type of substrate 112b), having a plurality of chiplets, to the first buffer. The method 600, at 610, includes transferring the second type of substrate to a second atmospheric plasma activation module (e.g., plasma module 350) to activate the second type of substrate. In some embodiments, the second plasma activation module is the first plasma activation module. In some embodiments, the second plasma activation module is located in a separate transfer chamber or plasma activation chamber than the first plasma activation module. For example, in some embodiments, the first plasma activation module may be disposed in a first transfer chamber of a first AMM and the second plasma activation module may be disposed in a second transfer chamber of a second AMM different than the first AMM. In some embodiments, the first plasma activation module may be disposed in a first plasma activation chamber coupled to the first AMM, and the second plasma activation module may be disposed in a second plasma activation chamber coupled to the second AMM. Ir In some embodiments, one of the first or second plasma activation modules may be disposed in a transfer chamber and the remaining of the first or second plasma activation modules may be disposed in a plasma activation chamber.

The method 600, at 612, includes transferring at least one of the plurality of activated chiplets from the second type of substrate to the activated first type of substrate in a bonder chamber (e.g., bonder chamber 140) of a first AMM of the plurality of AMMs. The method 600, at 614, includes bonding the at least one of the plurality of activated chiplets to the activated first type of substrate in the bonder chamber. The method 600 may include removing the bonded substrate from the multi-chamber processing tool via the one or more loadports.

While the foregoing is directed to embodiments of the present disclosure, other and further embodiments of the disclosure may be devised without departing from the basic scope thereof.

1. A multi-chamber processing tool, comprising:
an equipment front end module (EFEM) having one or more loadports for receiving one or more types of substrates;
a plurality of atmospheric modular mainframes coupled to each other and having a first atmospheric modular mainframe coupled to the EFEM, wherein each of the plurality of atmospheric modular mainframes include a transfer chamber and one or more process chambers coupled to the transfer chamber, wherein at least one of the plurality of atmospheric modular mainframes includes a bonder chamber, wherein the transfer chamber includes a buffer having a plurality of shelves for supporting the one or more types of substrates and includes a transfer robot; and
an atmospheric plasma activation module disposed in the transfer chamber or one of the one or more process chambers.

2. The multi-chamber processing tool of claim 1, wherein the atmospheric plasma activation module is disposed in the transfer chamber of the one of the plurality of atmospheric modular mainframes.

3. The multi-chamber processing tool of claim 2, wherein the transfer robot is configured to transfer the one or more types of substrates between the buffer, the one or more process chambers, and a buffer disposed in an adjacent atmospheric modular mainframe of the plurality of atmospheric modular mainframes and configured to index the one or more types of substrates with respect to the atmospheric plasma activation module.

4. The multi-chamber processing tool of claim 1, wherein the atmospheric plasma activation module is disposed in a plasma activation chamber of the one or more process chambers of the one or more of the plurality of atmospheric modular mainframes.

5. The multi-chamber processing tool of claim 4, wherein the plasma activation chamber includes a plasma activation stage, and wherein at least one of the plasma activation stage or the atmospheric plasma activation module is configured to move laterally within the plasma activation chamber.

6. The multi-chamber processing tool of claim 1, wherein the atmospheric plasma activation module is sized smaller than the one or more types of substrates.

7. The multi-chamber processing tool of claim 1, wherein the atmospheric plasma activation module is disposed above a plasma activation stage that is configured to rotate.

8. The multi-chamber processing tool of claim 1, wherein a first of the plurality of atmospheric modular mainframes include a wet clean chamber, a degas chamber, and a plasma activation chamber.

9. The multi-chamber processing tool of claim 1, wherein the transfer chamber is a non-vacuum chamber.

10. A multi-chamber processing tool, comprising:
an equipment front end module (EFEM) having one or more loadports for receiving one or more types of substrates; and
a plurality of atmospheric modular mainframes coupled to each other and having a first atmospheric modular mainframe coupled to the EFEM, wherein each of the plurality of atmospheric modular mainframes include a transfer chamber and one or more process chambers coupled to the transfer chamber, wherein at least one of the plurality of atmospheric modular mainframes include a bonder chamber and at least one of the plurality of atmospheric modular mainframes include a plasma activation stage for supporting a substrate of the one or more types of substrates, wherein the transfer chamber includes a buffer configured to hold a plurality of the one or more types of substrates and includes a transfer robot configured to transfer the one or more types of substrates between the buffer, the one or more process chambers, and a buffer disposed in an adjacent atmospheric modular mainframe of the plurality of atmospheric modular mainframes; and
an atmospheric plasma activation module configured to form an atmospheric pressure plasma and to expose a surface of the substrate to the atmospheric pressure plasma, wherein the plasma activation stage is configured to move with respect to the atmospheric plasma activation module.

11. The multi-chamber processing tool of claim 10, wherein the plasma activation stage includes a slot and an actuator configured to move the one or more types of substrates laterally via the slot.

12. The multi-chamber processing tool of claim 10, wherein the plasma activation stage is disposed in the transfer chamber and is configured to move the one or more types of substrates laterally within the transfer chamber.

13. The multi-chamber processing tool of claim 10, wherein the atmospheric plasma activation module is disposed in a plasma activation chamber of the one or more process chambers of the one or more of the plurality of atmospheric modular mainframes.

14. The multi-chamber processing tool of claim 13, wherein the plasma activation chamber includes a motion system coupled to the atmospheric plasma activation module, wherein the motion system is configured to move the atmospheric plasma activation module.

15. A method of bonding a plurality of chiplets onto a substrate, comprising:
loading a first type of substrate onto a first loadport of an equipment front end module (EFEM) of a multi-chamber processing tool having a plurality of atmospheric modular mainframes;
using an EFEM robot to transfer the first type of substrate to a first buffer disposed in a first atmospheric modular mainframe of the plurality of atmospheric modular mainframes coupled to the EFEM;
transferring the first type of substrate to a first atmospheric plasma activation module to activate the first type of substrate;
using the EFEM robot to transfer a second type of substrate, having a plurality of chiplets, to the first buffer;
transferring the second type of substrate to a second atmospheric plasma activation module to activate the plurality of chiplets of the second type of substrate;
transferring at least one of the plurality of activated chiplets from the second type of substrate to the activated first type of substrate in a bonder chamber of a first atmospheric modular mainframe of the plurality of atmospheric modular mainframes; and
bonding the at least one of the plurality of activated chiplets to the activated first type of substrate in the bonder chamber.

16. The method of claim 15, wherein the second atmospheric plasma activation module is the first atmospheric plasma activation module.

17. The method of claim 15, wherein the first type of substrate is activated in a first plasma activation chamber via the first atmospheric plasma activation module.

18. The method of claim 15, wherein the first type of substrate is activated in a transfer chamber of one of the plurality of atmospheric modular mainframes.

19. The method of claim 15, wherein the first type of substrate is activated via indexing the first type of substrate with respect to the first atmospheric plasma activation module.

20. The method of claim 15, wherein the first type of substrate is activated at atmospheric pressure.
